(19) United States
(12) Patent Application Publication
(10) Pub. No.: US 2008/0277747 A1
(43) Pub. Date: Nov. 13, 2008

(54) MEMS device support structure for sensor packaging

(76) Inventor: Nazir Ahmad, San Jose, CA (US)

Correspondence Address: NAZIR AHMAD, 739 SEAWOOD WAY, SAN JOSE, CA, 95120, US

(21) Appl. No.: 12/151,771

(22) Filed: May 8, 2008

Related U.S. Application Data
(60) Provisional application No. 60/928,282, filed on May 8, 2007.

(51) Int. Cl. H01L 29/84; H01L 21/00

(52) U.S. Cl. 257/415; 438/50; 257/E21.001; 257/E29.324

(57) ABSTRACT

A sensor device and a method of forming comprises a die pad receives a MEMS device. The MEMS device has a first coefficient of thermal expansion (CTE). The die pad is made of a material having a second CTE compliant with the first CTE. The sensor device includes a support structure with a CTE not compliant with the first and second CTE. The support structure has a cylindrical port that protrudes from a base and is coupled to the die pad. The cylindrical port has a height and wall thickness which minimize forces felt by the die pad and MEMS device when the support structure undergoes thermal expansion or contraction. The base and cylindrical port can have different or similar outer diameters. The die pad has an aperture which communicates with an aperture of the MEMS device, whereby the die pad aperture has a smaller diameter than the MEMS aperture.

### CROSS-REFERENCE TO RELATED APPLICATIONS

This application claims the benefit of priority based on U.S. Provisional Patent ion Ser. No. 60/928,282 filed on May 8, 2007 in the name of the present inventor and “DIE SUPPORT DESIGN FOR PACKAGING A SENSOR”.

### FIELD OF INVENTION

The present invention relates generally to sensor system packaging, and specifically to or stress free packaging of Micro-Electro-Mechanical System (MEMS) pressure sensors.

### BACKGROUND INFORMATION

The use of MEMS (micro-electro-mechanical systems) sensors is becoming widespread in applications where a small sensor is needed and low cost is important. In applications where the sensor is exposed to harsh environments, such as that in refrigeration and AC systems, a backside entry sensor device is used because the topside of the sensor, which usually contains the piezo-resistive elements, cannot be exposed to the harsh conditions in the environment.

A MEMS sensor is usually used in the sensor device and attached to a support structure which is then welded or crimped to a pressure port. Support structures have a high thermal expansion mismatch between the support material and the MEMS sensor. This mismatch may cause strain, unrelated to pressure, which results in unintended results and errors in the sensor measurements. Accordingly, minimal or stress free installation of the MEMS die is an important aspect of making reliable and better performing pressure sensors.

One method to reduce the strain between the MEMS sensor and the support structure is to use a thermally compliant die attach made of a silicone elastomer. However silicone elastomers may not provide a hermetic seal, thereby allowing gas or liquid to leak into the section of the sensor device having the electronic components therein when high temperatures or pressures are present in the environment surrounding the sensor device. This may cause the sensor device to leak, thereby adversely affecting the sensor readings and yielding inconsistent and inaccurate measurements. In addition, refrigeration systems and sensor systems therein are not allowed any gas or liquid leaks for environmental safety reasons as regulated by the Environmental Protection Agency (EPA).

### BRIEF SUMMARY

A sensor device and a method of forming comprise a die pad which receives a MEMS device. The MEMS device has a first coefficient of thermal expansion (CTE). The die pad is made of a material having a second CTE compliant with the first CTE. The sensor device includes a support structure with a CTE not compliant with the first and second CTE. The support structure has a cylindrical port that protrudes from a base and is coupled to the die pad. The cylindrical port has a height and wall thickness which minimize forces felt by the die pad and MEMS device when the support structure undergoes thermal expansion or contraction. The base and cylindrical port can have different or similar outer diameters. The die pad has an aperture which communicates with an aperture of the MEMS device, whereby the die pad aperture has a smaller diameter than the MEMS aperture.

### BRIEF DESCRIPTION OF THE DRAWINGS

The accompanying drawings, which are incorporated into and constitute a part of this specification, illustrate one or more examples of embodiments and, together with the description of example embodiments, serve to explain the principles and implementations of the embodiments.

In the drawings:

FIGS. 1A and 1B illustrate exploded views of the sensor system in accordance with one or more embodiments.

FIGS. 2A and 2A′ illustrates perspective views of a support structure in accordance with an embodiment.

FIG. 2B illustrates a cross-sectional view of the support structure in FIG. 2A in accordance with an embodiment.

FIG. 3 illustrates a cross-sectional view of a support structure in accordance with an embodiment.

FIG. 4A illustrates perspective views of a die pad and a support structure in accordance with an embodiment.

FIG. 4B illustrates a cross-sectional view of the die pad in FIG. 4A in accordance with an embodiment.

FIG. 5A illustrates a cross-sectional view of the die pad in accordance with an embodiment.

FIG. 5B illustrates a cross-sectional view of the die pad coupled to the support structure in accordance with an embodiment.

FIG. 6A illustrates a cross-sectional view of a die pad in accordance with an embodiment.

FIG. 6B illustrates a cross-sectional view of a die pad coupled to a support structure in accordance with an embodiment.

FIG. 7 illustrates a cross-sectional view of a die pad in accordance with an embodiment.

FIG. 8 illustrates a cross-sectional view of a die pad coupled to a support structure for Ni/Au plating in accordance with an embodiment.

FIG. 9 illustrates a flow chart of the production and assembly process of the sensor system in accordance with an embodiment.

### DETAILED DESCRIPTION

Example embodiments are described herein in the context of a sensor system. Those of ordinary skill in the art will realize that the following description is illustrative only and is not intended to be in any way limiting. Other embodiments will readily suggest themselves to such skilled persons having the benefit of this disclosure. Reference will now be made in detail to implementations of the example embodiments as illustrated in the accompanying drawings. The same reference indicators will be used throughout the drawings and the following description to refer to the same or like items.

In the interest of clarity, not all of the routine features of the implementations described herein are shown and described. It will, of course, be appreciated that in the development of any such actual implementation, numerous implementation-specific decisions must be made in order to achieve the developer's specific goals, such as compliance with application- and business-related constraints, and that these specific goals will vary from one implementation to another and from one developer to another. Moreover, it will be appreciated that such a development effort might be complex and time-consuming, but would nevertheless be a routine undertaking of engineering for those of ordinary skill in the art having the benefit of this disclosure.

In accordance with this disclosure, the components, process steps, and/or data structures described herein may be implemented using various types of operating systems, computing platforms, computer programs, and/or general purpose machines. In addition, those of ordinary skill in the art will recognize that devices of a less general purpose nature, such as hardwired devices, field programmable gate arrays (FPGAs), application specific integrated circuits (ASICs), or the like, may also be used without departing from the scope and spirit of the inventive concepts disclosed herein. Where a method comprising a series of process steps is implemented by a computer or a machine and those process steps can be stored as a series of instructions readable by the machine, they may be stored on a tangible medium such as a computer memory device (e.g., ROM (Read Only Memory), PROM (Programmable Read Only Memory), EEPROM (Electrically Erasable Programmable Read Only Memory), FLASH Memory, Jump Drive, and the like), magnetic storage medium (e.g., tape, magnetic disk drive, and the like), optical storage medium (e.g., CD-ROM, DVD-ROM, paper card, paper tape and the like) and other types of program memory.

Typically, Kovar die pads hold the MEMS die thereon and are electroplated with nickel (Ni) and gold (Au) for corrosion protection. The MEMS die is typically attached to the die pad by a gold and tin (80/20) eutectic solder alloy. The use of this solder alloy and Kovar material combination is a well known die attachment method as the CTEs of Kovar and Si/Glass based MEMS dies are similar. In the present state of the art, a disk like die pad is attached to a stainless steel header to complete the mechanical aspect of the sensor package. The thermal expansion and contraction of the steel header, however, imparts significant stresses to the die pad. This can cause the glass constraint on the bottom of the MEMS die to crack or cause irregular behavior in the MEMS device.

Another disadvantage with the existing sensor packages relates to the need of Ni and Au plating of the disc like Kovar die pad for corrosion protection. In addition, the Ni/Au plating must provide an oxide free soldering surface to allow attachment with the MEMS device. However, the presence of Au on the Kovar die pad inhibits its ability to create a hermetic seal with the rest of the packaging when laser welded to the stainless steel header. It is possible to remove the Au from a portion of the perimeter of the disc like Kovar die pad to allow it to be laser welded to the stainless steel header. The aforementioned disadvantage leaves some exposed areas of the un-plated Kovar around the laser weld which will be subject to corrosion problems. The stress in the disc-shaped Kovar die pad is difficult to manage, because the disc shaped configuration does not isolate stresses created in the steel header due to thermal expansion and contraction and prevent those stresses from reaching the MEMS die.

In general, the specification describes one or more embodiments directed to packaging for housing sensor or other devices in which the packaging is subject to stresses and configured to prevent those stresses from affecting the devices housed therein. The sensor package described herein utilizes a die pad made of a material having a low coefficient of thermal expansion (CTE) with a support structure which has a relatively higher CTE to provide a very low cost die pad and support structure for the sensor device.

It is preferred that the sensor device is a MEMS (Micro-Electro-Mechanical System), however the packaging may be additionally or alternatively used for other types of devices such as ASICs, ICs, etc. The subject matter described herein allows the inexpensive manufacture of an effective sensor system which may be used for absolute sensors, gage type sensors, AC and refrigeration systems sensors, braking sensors and/or other engine control sensors in vehicles, industrial and/or medical equipment. The MEMS may be a pressure sensor, temperature sensor, Hall effect sensor, electromagnetic sensor and sensor arrays, humidity sensor, optical sensor, gyroscope, accelerometer, piezoelectric sensor or transducer, and a display. The particulars of how the MEMS is constructed is not described herein, but it should be noted that any type of MEMS or similar device is contemplated for use with the package described herein.

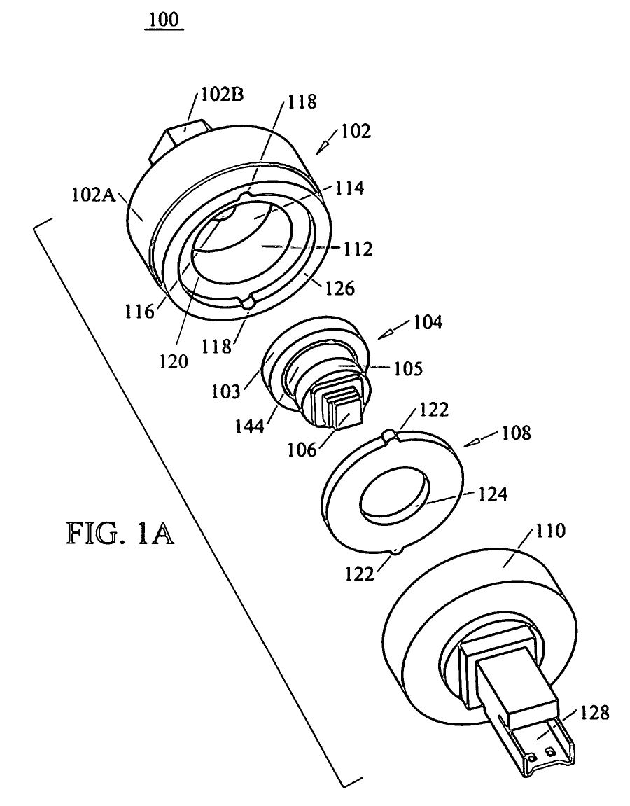

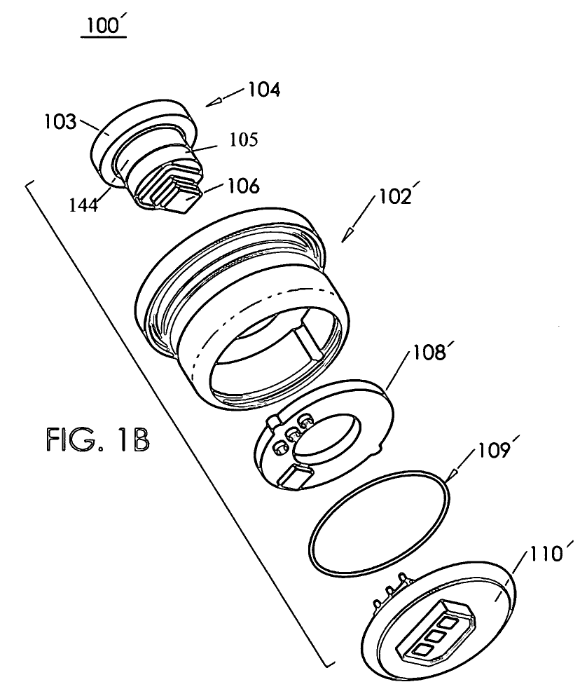

FIG. 1A illustrates an exploded view of the sensor system in accordance with an embodiment. As shown in FIG. 1A, the sensor system 100 includes a header 102, a support structure 104 having a base 103, a die pad port 144 and a die pad 105 coupled thereto. A sensor device 106 is mounted onto the die pad 105. The header 102 includes a cavity 112 in which the base 103 fits against a surface 114. A printed circuit board 108 and a connection cap 110 are coupled to the assembly to form the overall package. It should be noted that additional and/or alternative components may be utilized in the sensor system 100 without departing from the scope of the claimed embodiments herein.

The header 102 (FIG. 1A) includes an upper portion 102A and a lower portion 102B, whereby the lower portion 102B connects, via a pressure port 116, the sensor system to a relatively highly pressurized environment which is being measured by the system 100. The lower portion 102B is shown as a bolt member in FIG. 1A, but may have any other appropriate design based on the port configuration of the item to which the header 102 is coupled. For example, the bottom portion 102B of the header may have a threaded configuration to allow the header to be screwed into a mounting port.

The upper portion 102A of the header is made of a metal in an embodiment. For example, the header could be made from any type of stainless steel such as 304 or 316 series or other metallic materials such as Aluminum or others by machining, casting or molding such as metal injection molding where appropriate.

As shown in FIG. 1A, the header 102 also receives a printed circuit board (PCB) 108 in a second recess having a PCB seating area 120 in the upper portion 102A in an embodiment. In an embodiment, the PCB 108 is coupled to the seating area 120 by an adhesive, although any other appropriate coupling method is contemplated. In an embodiment, the PCB 108 includes guide extensions 122 which fit within corresponding notches 118 in the header 102 when the PCB 108 is received in the PCB seating area 120. In an embodiment, the guide extensions 122 are keyed, such that the PCB 108 will only properly fit within the PCB seating area 120 when properly oriented. In an embodiment, the PCB has a donut configuration which includes an aperture 124 which extends therethrough, whereby the aperture 124 is configured to be aligned with the sensor 106 and surround the sensor 106 when the PCB 108 is mounted to the header. In an embodiment, the sensor 106 is wire bonded to the PCB 108, although any other appropriate electrical coupling method is contemplated. The aperture 124 of the PCB 108 also allows electrical connections to be easily made between the sensor 106, the PCB 108 and the connection cap 110.

The connection cap 110 fits into the outer recess 126 in the upper portion of 102A and fits over the components and electronics within the upper portion 102A of the header 102. The connection cap 110 may be mounted to the header by any appropriate methods. The connection cap 110 includes an electrical connection port 128 which allows power, signals and/or data to flow between the sensor system 100 and any other electrical components.

FIG. 1B illustrates another embodiment of the system 100′ in which the support structure 104, including base 103, die pad port 144, die pad 105 and sensor device 106 are inserted through a bottom surface of a header 102′. In addition, the PCB board 108′ (with an ASIC coupled thereto) is coupled to the header 102′ via a top surface along with an O-ring 109′ and a connector 110′ to form the entire package assembly. It should be noted that the die pad package described herein is not limited to the systems described in FIGS. 1A and 1B and may be used in a variety of different systems in a variety of applications.

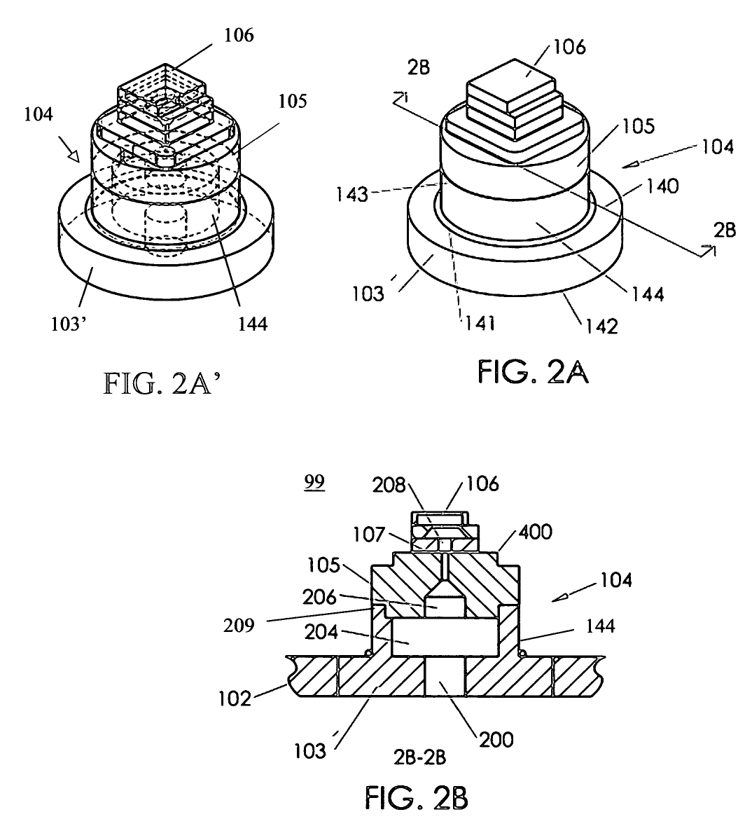

FIGS. 2A, 2A′ and 2B illustrate the invention in accordance with an embodiment. As shown in the Figures, the die pad assembly includes the support structure 104 coupled to the die pad 105, and a MEMS device 106 coupled to the die pad 105. In an embodiment, the support structure 104 includes a cylindrical base 103′, preferably made of stainless steel, which is installed in the header 102 (FIG. 2B). The base 103′ has a top surface 140 and a bottom surface 142. A cylindrical die pad port 144, shown as a circular tube, extends orthogonally from the top surface 140 and is configured to be hermetically sealed with respect to the base 103′ at the junction 141. In an embodiment, the die pad port 144 is an integral with the base 103′, whereby the support structure is manufactured as one component. In an embodiment, the die pad port 144 and the base 103′ are separate pieces which are attached to one another at junction 141 but form a hermetic seal therebetween. In another embodiment the top of die pad port 144 is attached to the die pad at junction 143 shown in FIG. 2A. The cylindrical die pad port includes a receiving aperture 146 (FIG. 4A) and a conduit 204 (FIG. 2B) in communication with the receiving aperture 146. The receiving aperture 146 has a diameter configured to securely receive and align the die pad 105 with or without fixtures before joining by laser welding or other means to achieve a hermetic seal.

As stated, the support structure 104 is coupled to a source of pressurized media, whereby in an embodiment, the MEMS measures one or more conditions of the media. The media (e.g. gas, liquid, or mixture thereof) from the system 99, as shown in FIG. 2B, travels from the system via the conduit 200 in the base 103′ of the support structure 104 via the inner tubular cavity 204, up the conduit 206 in the die pad 105 to a corresponding aperture 208 of the MEMS device 106. Upon reaching the underside of the die portion of the MEMS device 106, the media travels through the aperture in the die portion into the MEMS device 106 itself, whereby the MEMS device 106 measures a characteristic of the media.

The configuration of the support structure 104 and die pad 105 reduces the stresses caused by the header 102 (FIGS. 1A and 2B) and particularly during thermal cycling of the device. The support structure 104 has a cantilever type structure in relation to the header 102, whereby the support structure 104 isolates the MEMS 106 from experiencing the thermal stresses and strains which are applied to the support structure 104 during operation (e.g. when the MEMS package is used in a refrigeration system). In particular, the tubular wall 144 of the die pad port has height and wall thickness dimensions which inhibit the stresses and strains induced by the thermal expansion and contraction of the header 102 to reach the die pad 105 and sensor 106. Thus, at appropriate height and wall thickness dimensions, the forces from the header 102 will diminish as they travel along the die pad support wall 144 such that the MEMS device 106 will not experience any adverse or negative force effects.

As shown in FIG. 2B, the conduit 200 has a diameter which is equal to the diameter of the port conduit 206. However, it is contemplated that the base conduit 200 may have a diameter which is less than or greater than the diameter of the port conduit 206. In an embodiment, the base 103′ has an overall outer diameter of 10 millimeters (mm) and a thickness of the base is 2.5 mm. The base conduit 200 has a diameter of 2.5 mm. In addition, the die pad port 144 has an outer diameter of 4.5 mm, a height of 2.5 mm and wall thickness of 0.5 mm.

It should be noted that the above described dimensions of the components described herein are provided as an example for one or more applications in which the support structure 104 is made of stainless steel and the die pad 105 made of Kovar. Thus, it is contemplated that the assembly will have different dimensions based upon the application in which it is used as well as the type of materials of the individual components of the assembly.

For example, the support structure 104 shown in FIGS. 2A and 2B has a stainless steel base 103′ of up to approximately 15 mm in diameter and up to 6 mm in height. The die pad port 144 in the embodiment in FIG. 2A has an outer diameter of up to 8 mm, a height of up to 6 mm, and wall thickness of up to 1 mm. In an embodiment, the die pad port may be between 3.0 to 15.0 mm in outer diameter and the height may be between 2.0 and 10.0 mm. The wall thickness of 144 is below 2.0 mm and preferably in the range of 0.2 to 0.5 mm. Longer and thinner walls of the die pad port 144 are preferred embodiments. These and/or other dimensions may be selected depending on the design requirements and the materials involved.

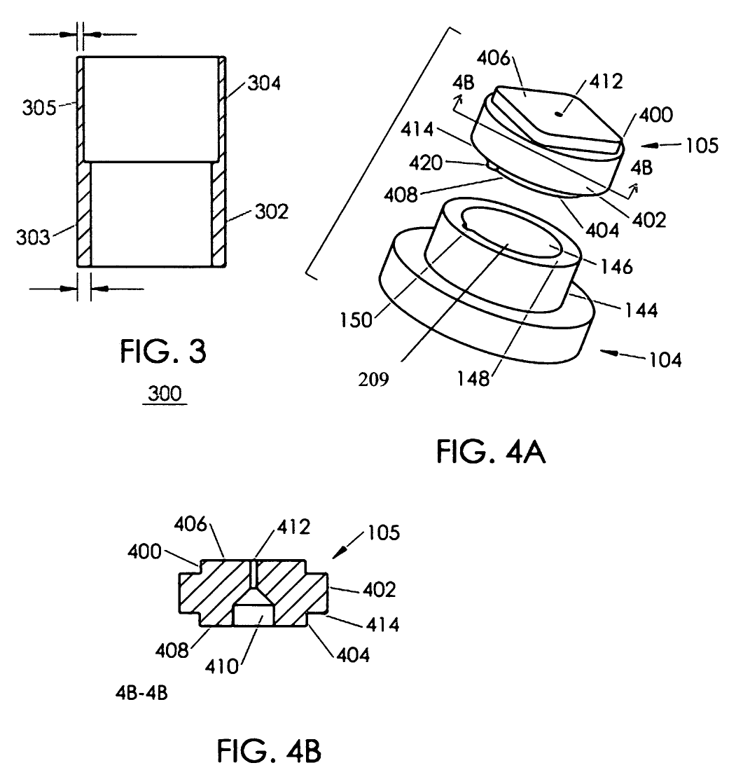

It should be noted that the die pad assembly is not limited to the configuration shown in FIGS. 2A and 2B. In an embodiment, as shown in FIG. 3, the base 302 of the support structure 300 has an outer diameter which is substantially the same as the diameter of the die pad port 304. However, as shown in FIG. 3, the base portion 302 has a wall thickness 303 which is greater than the wall thickness 305 of the die pad port 304. In the embodiment shown in FIG. 3, the support structure has an overall height between 4 and 12 mm, whereby the height of the base portion is between 2 and 6 mm and the height of the die pad port is between 2 and 6 mm. The base of the support structure has an outer diameter between 6 and 12 mm and a wall thickness dimension between 1 and 2 mm. The wall thickness 305 of the die pad port 304 is in the range of 0.2 to 0.5 mm. In an embodiment, the base of the support structure has an outer diameter which is larger than the diameter of the die pad port. It should be noted, however, other dimensions are contemplated for the support structure in the embodiments described above depending on the materials used as well as the specific applications in which the MEMS packaging will be used.

FIG. 4A illustrates an exploded view of the die pad 105 and support structure 104 in accordance with an embodiment. FIG. 4B illustrates a cross sectional view of the embodiment shown in FIG. 4A along lines 4B-4B. As shown in the embodiment in FIGS. 4A and 4B, the die pad 105 includes a MEMS receiving platform 400, a main body 402, and an interface portion 404. The die pad 105 also includes a shoulder 414 region adjacent to the interface portion 404, whereby the shoulder 414 portion directly contacts the rim 148 of the die pad port 144 when the die pad 105 is coupled (and preferably laser welded) to the support structure 104. In an embodiment, as shown in FIG. 4A, the interface portion 404 has a protrusion 420 which serves as a key that fits into a corresponding notch 150 in the support structure 104 to ensure proper orientation of the die pad 105.

As shown in FIG. 4B, the die pad 105 is a solid piece with a conduit 410 which runs from a top surface 406 of the receiving platform 400 to a bottom surface 408 of the interface portion 404. In an embodiment, the entire height of the die pad, from the surface 406 to the surface 408, is 7 mm, although other dimensions are contemplated and may be used. The die pad is made of Kovar in an embodiment, although other materials may be used depending on the material and CTE of MEMS die and support structure such that stresses are isolated and not transferred from the support structure to the MEMS device. As stated, the die pad may be made of Invar in an embodiment.

In an embodiment, at least a portion of the die pad 105 is covered with a Ni or Ni/Au plating layer to provide corrosion protection and an oxide free surface to attach the MEMS onto the die pad 105. In an embodiment, the die portion of the MEMS 106 is attached to the die pad 105 using a Au/Sn (80/20) eutectic alloy to create a hermetic seal therebetween. It should be noted, however, that the above mentioned eutectic alloy is just an example and other compositions are contemplated. Further, other coupling technologies besides a eutectic alloy may be employed to attach the MEMS 106 to the die pad 105.

The receiving platform 400 (FIG. 2B) is configured to engage the die 106 of the MEMS. In an embodiment, the MEMS die 106 is made of a metallized glass, whereby the metallized glass die is solder attached at 107 to the receiving platform. In an embodiment, the MEMS die 106 may be made of silicon and glass. Other combination of materials such as silicon and silicon are contemplated. In addition to the gold/tin, tin based soft solder materials for die attach are also contemplated. The dimensions of the receiving platform 400 is preferably larger than the corresponding dimensions of the MEMS die 106 to prevent overhang of the MEMS die 106 with respect to the receiving platform 400.

As shown in the FIGS. 4A and 4B, an aperture 412 on the top surface 406 communicates with the conduit 410 and is positioned to align with the corresponding port aperture 208 in the MEMS device 106 (FIG. 2B). As shown in Figures, the receiving platform 400 is raised a certain height with respect to the main body 402, although it is not necessary.

It has been found that the relative sizes of the aperture 412 (FIGS. 4A, 4B) in the die pad with the aperture 208 in the MEMS die 106 (FIG. 2B) is very important, especially when the MEMS die 106 is attached to the receiving platform 400 using a eutectic solder. For example, for a MEMS die which is made of metallized glass, the eutectic solder may cause stress on the overhanging edge of the aperture port, thereby resulting in cracking of the glass around the aperture port of the MEMS die. Accordingly, it is preferred that the aperture 412 of the die pad be smaller in diameter than the port 208 of the MEMS die 106. In an embodiment, it is preferred that the aperture of the receiving platform is 0.35 mm-0.50 mm in diameter for a MEMS die having a port diameter of 0.8 mm. It should be noted that other diameters of the receiving platform aperture is contemplated based on the port diameter of the MEMS device and is not limited to the range of diameters described above.

The interface portion 404 of the die pad 105 shown in FIGS. 4A and 4B fits within the receiving aperture 209 of the support structure 104 (FIGS. 2B and 4A). As shown in the embodiment in FIG. 4B, the interface portion 404 protrudes downward perpendicular to the adjacent horizontal shoulder 414 of the main body 402. In an embodiment, the outer diameter of the interface portion 404 is slightly smaller than the inner diameter of the receiving aperture 209 of the support structure 104 to allow the interface portion 404 to fit inside the support structure 104 when the die pad 105 is coupled thereto (FIG. 2B). In an embodiment, the outer diameter of the main body 402 is substantially the same as the outer diameter of the die pad port 144 of the support structure 104. In an embodiment, the outer diameter of the main body of the die pad is larger than the outer diameter of the cylindrical portion of the support structure.

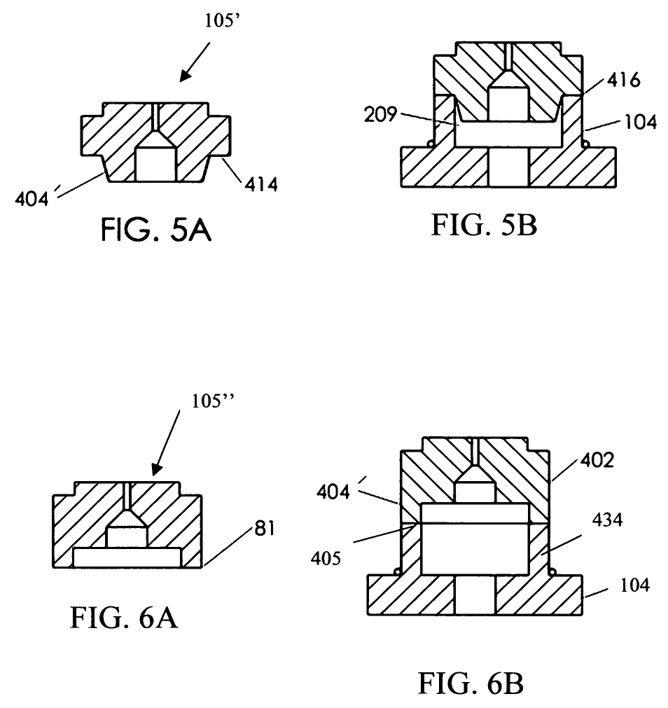

In an embodiment, as shown in FIGS. 5A and 5B, an interface portion 404′ of a die pad 105′ protrudes downward at an angle with respect to the horizontal shoulder 414. The angled configuration of the interface portion 404′ allows the shoulders 414 to be attached to a rim 416 of the support structure 104 adjacent to a receiving aperture 209, preferably by laser welding, and allows the interface portion 404′ to be plated with the Ni or Ni/Au layer to prevent corrosion.

In an embodiment, as shown in FIGS. 6A and 6B, the interface portion 404′ of a die pad 105″ has a diameter which is equivalent to the outer wall diameter of the main body 402, whereby the wall thickness of the interface portion 404′ is substantially the same as the wall thickness of the receiving cylinder 434 of the support structure 104. In an embodiment, the end of the receiving cylinder 434 and end 81 of the die pad 105″ are laser welded to create an interface 405 with a weld bead to the corresponding ends of the receiving cylinder, as shown in FIG. 6B. In an embodiment, the die pad is integral with the support structure 104 as one piece. This configuration allows the Ni/Au plating to be applied to the interface portion and coupled areas to provide corrosion protection.

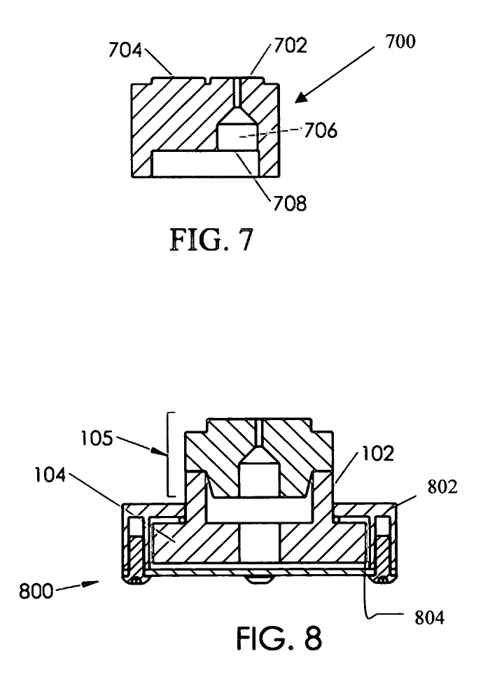

FIG. 7 illustrates a diagram of a die pad 700 in accordance with an embodiment. As depicted in FIG. 7, the overall diameter of the die pad 700 is configured to accommodate more than one electronic devices. In an example, the diameter of the die pad is 10 mm to allow it to accept a MEMS as well as an ASIC device. A first receiving platform 702 for the MEMS device is indicated in the figure as having a conduit 706 running from the receiving platform 702 to the bottom surface 708. Additionally, a second receiving platform 704 adjacent to the first receiving platform 702 accepts the ASIC device or other type of electronic device.

Although it is discussed that the die pads are laser welded to the support structure, the die pads can be brazed or eutectic soldered after applied with the Ni or Ni/Au plating along with the support structure. The support structure and die pad as well as the coupled areas between the two may be selectively plated, considering that the portion of the support structure that is subsequently coupled to the header must be free of gold for laser welding. A fixture 800 to achieve this is shown in FIG. 8, whereby the fixture 800 is a plastic enclosure in which the support structure 104 is inserted to protect it from the plating, but yet providing exposure to the die pad 105 to allow it to be plated. In addition, the fixture 802 is configured to provide an electrical contact 804 for the electroplating process as shown. The enclosure is leak tight to avoid the electroplating solution from getting to the support structure.

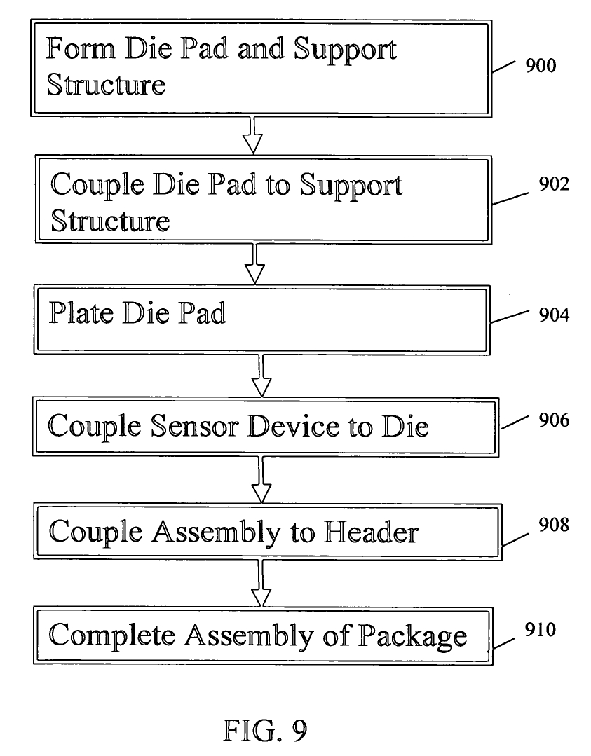

FIG. 9 illustrates a flow chart of the production and assembly process of the sensor assembly in accordance with an embodiment. Initially, the support structure and die pad are formed (900) such as by machining, stamping or other known methods. In an embodiment, the die pad is made by metal injection molding and then combining it with the stainless steel support. In making both parts, the die pad support structure and the die pad may be made by metal injection molding, whereby the support structure and die pad are combined during the metal injection molding process or assembled after being fabricated separately by any appropriate manufacturing processes such as machining, casting, sheet metal working or molding such as injection molding.

Thereafter, the die pad is coupled to the receiving aperture of the support structure by an appropriate method (902). As stated above, in an embodiment, a Kovar die pad is laser welded to the base made of stainless steel. A die pad made and base made of respective materials other than Kovar and stainless steel may be coupled to one another based on another method. In an embodiment, the die pad is then selectively plated (904) with an anti-corrosion material such as a Ni/Au coating. The coating can be of other materials depending on the material of the die pad.

Thereafter, the sensor device, MEMS in an embodiment, is coupled to the receiving platform of the die pad (906), preferably using a eutectic soldering process. Again, other coupling methods besides a eutectic soldering process are contemplated based on the materials of the die pad and sensor device. The assembled component is then coupled to the header component, (908), by crimping, o-ring sealing, c-ring sealing or other known method. This is then followed by any other components such as a PCB board to complete the manufacture and assembly of the sensor package (910).

In an embodiment, a sensor device comprises a die pad adapted to receive a MEMS device thereon, the MEMS device having a first coefficient of thermal expansion (CTE), wherein the die pad is made of a material having a second CTE substantially compliant with the first CTE; and a support structure having a third CTE not compliant with the first CTE and second CTE, the support structure having a base and a cylindrical port protruding therefrom, the cylindrical port coupled to the die pad and having a height dimension and a wall thickness configured to minimize forces at the die pad when the support structure undergoes thermal expansion or contraction.

In an embodiment, a sensor device comprising: a MEMS device having a first coefficient of thermal expansion (CTE), the MEMS device having a port aperture on a bottom surface; a die pad adapted to receive the MEMS device on a top surface, the die pad made of a material having a second CTE substantially compliant with the first CTE, the die pad including a first conduit running therethrough to deliver media to the aperture of the MEMS device; and a support structure having a third CTE not compliant with the first CTE and second CTE, the support structure configured to minimize forces at the die pad and MEMS device when the support structure undergoes thermal expansion or contraction, the support structure having an upper portion and a lower portion and a second conduit running therethrough in communication with the first conduit, wherein the second conduit in the upper portion has a diameter larger than the diameter in the lower portion of the second conduit.

In an embodiment, a sensor device comprising: a MEMS device having a first coefficient of thermal expansion (CTE); a die pad adapted to receive the MEMS device thereon, wherein the die pad is made of a material having a second CTE substantially compliant with the first CTE; and a support structure having a third CTE not compliant with the first CTE and second CTE, the support structure having a base and a cylindrical port protruding therefrom, the cylindrical port coupled to the die pad having a height dimension and a wall thickness configured to minimize forces at the die pad and MEMS device when the support structure undergoes thermal expansion or contraction.

In an embodiment, a method for forming a sensor device comprising: forming a die pad adapted to receive a MEMS device thereon, the MEMS device having a first coefficient of thermal expansion (CTE), wherein the die pad is made of a material having a second CTE substantially compliant with the first CTE; forming a support structure having a third CTE not compliant with the first CTE and second CTE, the support structure having a base and a cylindrical port protruding therefrom; and coupling the die pad to a receiving aperture of the cylindrical port, wherein the cylindrical port has a height dimension and a wall thickness configured to minimize forces at the die pad when the support structure undergoes thermal expansion or contraction.

In one or more embodiments, the die pad is made of either Invar or Kovar and the support structure is made of steel or aluminum. The support structure can have a uniform outer diameter or different portions of different diameters. In an embodiment, the die pad is coupled to the support structure by a laser welding process. In an embodiment, the die pad includes a Nickel-Gold layer thereon. In an embodiment, the die pad is configured to receive at least one device other than the MEMS device, such as another MEMS device and/or an ASIC device. In an embodiment, the die pad includes a conduit passing from a bottom surface to a top surface to define a first aperture in the top surface, the first aperture adapted to be in communication with a corresponding aperture of the MEMS device, wherein the first aperture has a diameter smaller than the corresponding aperture of the MEMS device. In an embodiment, the die pad includes an interface portion protruding from a bottom surface and adjacent to a shoulder of the die pad, the interface portion configured to fit within a receiving aperture of the support structure to secure the die pad thereto, wherein the interface portion extends substantially perpendicular or at an angle with respect to the shoulder.

While embodiments and applications have been shown and described, it would be apparent to those skilled in the art having the benefit of this disclosure that many more modifications than mentioned above are possible without departing from the inventive concepts disclosed herein. The invention, therefore, is not to be restricted except in the spirit of the appended claims.

What is claimed is:

1. A sensor device comprising:
a die pad adapted to receive a MEMS device thereon, the MEMS device having a first coefficient of thermal expansion (CTE), wherein the die pad is made of a material having a second CTE substantially compliant with the first CTE; and
a support structure having a third CTE not compliant with the first CTE and second CTE, the support structure having a base and a cylindrical port protruding therefrom, the cylindrical port coupled to the die pad and having a height dimension and a wall thickness configured to minimize forces at the die pad when the support structure undergoes thermal expansion or contraction.

2. The sensor device of claim 1, wherein the die pad is made of Invar, Kovar, glass, silicon, or a ceramic material.

3. The sensor device of claim 1, wherein the support structure is made of steel.

4. The sensor device of claim 1, wherein the support structure is made of aluminum.

5. The sensor device of claim 1, wherein cylindrical port and the base have outer diameter dimensions substantially similar to one another.

6. The sensor device of claim 1, wherein the base has a wall thickness which is greater than the wall thickness of the cylindrical port.

7. The sensor device of claim 1, wherein the die pad is coupled to the support structure by a laser welding process.

8. The sensor device of claim 1, wherein the die pad includes a Nickel-Gold layer thereon.

9. The sensor device of claim 1, wherein the die pad includes a conduit passing from a bottom surface to a top surface to define a first aperture in the top surface, the first aperture adapted to be in communication with a corresponding aperture of the MEMS device, wherein the first aperture has a diameter smaller than the corresponding aperture of the MEMS device.

10. The sensor device of claim 1, wherein the die pad is configured to receive the MEMS device and at least one other device.

11. The sensor device of claim 10, wherein the at least one other device is an ASIC device.

12. A sensor device comprising:
a MEMS device having a first coefficient of thermal expansion (CTE), the MEMS device having a port aperture on a bottom surface;
a die pad adapted to receive the MEMS device on a top surface, the die pad made of a material having a second CTE substantially compliant with the first CTE, the die pad including a first conduit running therethrough to deliver media to the aperture of the MEMS device; and a support structure having a third CTE not compliant with the first CTE and second CTE, the support structure configured to minimize forces at the die pad and MEMS device when the support structure undergoes thermal expansion or contraction, the support structure having an upper portion and a lower portion and a second conduit running therethrough in communication with the first conduit, wherein the second conduit in the upper portion has a diameter larger than the diameter in the lower portion of the second conduit.

13. The sensor device of claim 12, wherein the die pad is made of either Invar, Kovar, glass, silicon, or ceramic material.

14. The sensor device of claim 12, wherein the support structure is made of steel.

15. The sensor device of claim 12, wherein the support structure is made of aluminum.

16. The sensor device of claim 12, wherein upper portion and the lower portion have outer diameter dimensions substantially similar to one another.

17. The sensor device of claim 12, wherein the die pad is coupled to the support structure by a laser welding process.

18. The sensor device of claim 12, wherein the die pad includes a Nickel-Gold layer thereon.

19. The sensor device of claim 12, wherein the die pad is configured to receive at least one device other than the MEMS device.

20. The sensor device of claim 19, wherein the at least one other device is an ASIC device.

21. The sensor device of claim 19, wherein the at least one other device is another MEMS device.

22. The sensor device of claim 12, wherein the die pad includes a conduit passing from a bottom surface to a top surface to define a first aperture in the top surface, the first aperture adapted to be in communication with a corresponding aperture of the MEMS device, wherein the first aperture has a diameter smaller than the corresponding aperture of the MEMS device.

23. The sensor device of claim 12, wherein the die pad includes an interface portion protruding from a bottom surface and adjacent to a shoulder of the die pad, the interface portion configured to fit within a receiving aperture of the support structure to secure the die pad thereto, wherein the interface portion extends substantially perpendicular to the shoulder.

24. The sensor device of claim 12, wherein the die pad includes an interface portion protruding from a bottom surface and adjacent to a shoulder of the die pad, the interface portion configured to fit within a receiving aperture of the support structure to secure the die pad thereto, wherein the interface portion extends at an angle with respect to the shoulder.

25. A sensor device comprising:
a MEMS device having a first coefficient of thermal expansion (CTE);
a die pad adapted to receive the MEMS device thereon, wherein the die pad is made of a material having a second CTE substantially compliant with the first CTE; and
a support structure having a third CTE not compliant with the first CTE and second CTE, the support structure having a base and a cylindrical port protruding therefrom, the cylindrical port coupled to the die pad having a height dimension and a wall thickness configured to minimize forces at the die pad and MEMS device when the support structure undergoes thermal expansion or contraction.

26. A method for forming a sensor device comprising:
forming a die pad adapted to receive a MEMS device thereon, the MEMS device having a first coefficient of thermal expansion (CTE), wherein the die pad is made of a material having a second CTE substantially compliant with the first CTE;
forming a support structure having a third CTE not compliant with the first CTE and second CTE, the support structure having a base and a cylindrical port protruding therefrom; and
coupling the die pad to a receiving aperture of the cylindrical port, wherein the cylindrical port has a height dimension and a wall thickness configured to minimize forces at the die pad when the support structure undergoes thermal expansion or contraction.

27. The method of claim 26, wherein the die pad is made of either Invar or Kovar.

28. The method of claim 26, wherein the support structure is made of steel.

29. The method of claim 26, wherein the support structure is made of aluminum.

30. The method of claim 26, wherein upper portion and the lower portion have outer diameter dimensions substantially similar to one another.

31. The method of claim 26, wherein the die pad is coupled to the support structure by a laser welding process.

32. The method of claim 26, wherein the die pad includes a Nickel-Gold layer thereon.

33. The method of claim 26, wherein the die pad is configured to receive at least one device other than the MEMS device.

34. The method of claim 33, wherein the at least one other device is an ASIC device.

35. The method of claim 33, wherein the at least one other device is another MEMS device.

36. The method of claim 26, wherein the die pad includes a conduit passing from a bottom surface to a top surface to define a first aperture in the top surface, the first aperture adapted to be in communication with a corresponding aperture of the MEMS device, wherein the first aperture has a diameter smaller than the corresponding aperture of the MEMS device.

37. The method of claim 26, wherein the die pad includes an interface portion protruding from a bottom surface and adjacent to a shoulder of the die pad, the interface portion configured to fit within a receiving aperture of the support structure to secure the die pad thereto, wherein the interface portion extends substantially perpendicular to the shoulder.

38. The method of claim 26, wherein the die pad includes an interface portion protruding from a bottom surface and adjacent to a shoulder of the die pad, the interface portion configured to fit within a receiving aperture of the support structure to secure the die pad thereto, wherein the interface portion extends at an angle with respect to the shoulder.
